(19) United States
(12) Patent Application Publication
(10) Pub. No.: US 2008/0136011 A1
(43) Pub. Date: Jun. 12, 2008

(54) Semiconductor device

(75) Inventor: Hirohiko Shibata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/000,159

(22) Filed: Dec. 10, 2007

(30) Foreign Application Priority Data
Dec. 11, 2006 (JP) 2006-333200

(51) Int. Cl. H01L 23/538

(52) U.S. Cl. 257/691; 257/E23.169

(57) ABSTRACT

A semiconductor device includes a first semiconductor chip having first connecting pads arranged at first interval and a second semiconductor chip having second connecting pads arranged at second interval, the second interval being larger than the first interval, in which the first semiconductor chip includes the first connecting pads not connected to the second connecting pads and the first connecting pads not connected to the second connecting pads function as tilt adjustment pads adjusting tilt of bonding wires connecting the first connecting pads and the second connecting pads.

### BACKGROUND OF THE INVENTION

1. Field of the Invention

The present invention relates to a semiconductor device, and, more particularly, to a semiconductor device forming an SiP (System in Package) in which a plurality of chips are packaged together.

2. Description of Related Art

In an SiP, a plurality of semiconductor chips having different functions are formed on a single substrate and packaged. The SiP has a plurality of semiconductor chips mounted in a semiconductor package. In the SiP, connection of wirings for transmitting or receiving signals between semiconductor chips is conducted and power is supplied to the semiconductor chips that are mounted. A terminal for transmitting/receiving signal to/from a device connected to the external part of the SiP is drawn to the external part of the SiP. Therefore, mobile device or the like employing the SiP is multi-functionalized, thinned, and light-weighted.

A semiconductor system employing such an SiP is disclosed in Japanese Unexamined Patent Application Publication No. 11-086546 (Takemae). The semiconductor system disclosed in Takemae is shown in FIG. 10. In a semiconductor system 90 shown in FIG. 10, a logic chip 92 and a memory chip 93 are provided in a package 91. The logic chip 92 and the memory chip 93 are adjacently provided so that one side of the logic chip 92 and one side of the memory chip 93 face with each other. The package 91 includes connecting terminals 94 connected to the logic chip 92 and the memory chip 93, terminals for I/O circuit power 95 to which power supply voltage Vcc and ground voltage Vss is supplied from external part through the connecting terminals 94, and I/O circuit power lines 96 supplying power supply voltage Vcc and ground voltage Vss. The terminals 97 are provided on the I/O circuit power lines 96. The connecting terminals 94 are connected to connecting terminals 98 provided on the logic chip 92 or the memory chip 93 by wire bondings, or the like.

Each of the logic chip 92 and the memory chip 93 has high-speed I/O circuits 99, I/O terminals 100, and I/O power supply terminals 101. The I/O terminals 100 and the I/O power supply terminals 101 are provided along the side in which the logic chip 92 and the memory chip 93 face with each other. The I/O terminals 100 on the logic chip 92 and the I/O terminals 100 on the memory chip 93 are electrically connected by bonding wires 102. The I/O power supply terminals 101 are connected to the terminals 97 formed on the I/O circuit power supply lines 96 by wire bondings or the like, and power is supplied to the I/O power supply terminals 101.

However, in the related semiconductor devices, distance between pads of the I/O terminals 100, which are the pads electrically connecting chips mounted on the SiP (hereinafter referred to as pad pitch), is assumed to be constant. Therefore, if the pad pitches of the logic chip 92 and the memory chip 93 are different, for example, bonding wires connecting I/O terminals 100 are not connected to be orthogonal to a side in which the logic chip 92 and the memory chip 93 face on the plane and the bonding wires are not connected to be substantially parallel to each other. Now we consider a case in which the I/O terminals 100 are sequentially connected from the ends of a pad line. For example, when a fifth I/O terminal 100 from the end of the pad line of the logic chip whose pad pitch is shorter and a fifth I/O terminal 100 from the end of the pad line of the logic chip whose pad pitch is longer are connected, the wire bonding is not connected to be orthogonal to the side in which the logic chips face to each other on the plane and the wire bonding tilts to the pad line direction because pad pitches are different between logic chips.

Hereinafter, the case in which pad pitches are not constant will be described. For example, the chip having high-quality central processing unit (CPU) embedded therein and the chip having peripheral circuit embedded therein may be mounted on a single SiP. In such a case, the chip having CPU and the chip having peripheral circuit have different manufacturing processes and different pad pitches. For example, the chip having CPU puts more emphasis on performance and it is designed and manufactured in the latest manufacturing process. In such a chip, chip price is high and high-speed operation is possible. On the other hand, the chip having peripheral circuit is manufactured by the manufacturing process that has conventionally been used. The price of such a chip is low. Therefore, the pad pitches may be different between chips because different chips have different manufacturing processes.

Further, not all the chips mounted on the single SiP are newly designed but the chip of some generations ago and the latest chip having new functions may be mixedly mounted. This is because if all the chips are newly designed and developed, TAT (Turn Around Time), which is the time needed for a series of process for development and manufacturing of the chips, becomes longer. Therefore, only the chip whose function is desired to be changed is newly redesigned. However, the manufacturing process is different between chips. Then the newly designed chip and the chip of some generations ago are mounted on the single SiP. Therefore, the chips having different pad pitches can be mounted on the SiP.

In such a case, the bonding wires used for connection are not connected to be orthogonal to the side in which the chips face to each other on the chip plane when the pads are sequentially connected from the ends of the pad line of the chips having different pad pitches. In other words, the bonding wires are not connected in substantially parallel because wiring length is different between bonding wires. Therefore, the bonding wires are not connected to be substantially orthogonal to the side in which the chips face to each other on the plane and the bonding wires may tilt to the pad line direction, which causes a problem that the bonding wires are shorted out when the bonding wires are encapsulated by the resin or the like.

### SUMMARY

To overcome the above-described problem, in one embodiment of the present invention, the semiconductor device includes a first semiconductor chip having first pads arranged at first interval and a second semiconductor chip having second pads arranged at second interval, the second interval being larger than the first interval, in which the first semiconductor chip includes the first pads not connected to the second pads and the first pads not connected to the second pads function as tilt adjustment pads adjusting tilt of wirings connecting the first pads and the second pads.

In one embodiment of the present invention, the first semiconductor chip have the first pads arranged at first interval, and the second semiconductor chip have the second pads arranged at second interval that is larger than the first interval. The first pads that are not connected to the second pads function as the tilt adjustment pads adjusting the tilt of the wirings connecting the first pads and the second pads. Therefore, it is possible to make the wirings substantially parallel by adjusting the tilt of the wirings connecting the first pads and the second pads.

According to one embodiment of the present invention, it is possible to easily connect chips having different pad pitches.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view of an SiP according to a present embodiment of the invention;

FIG. 2 is an enlarged view of a part of the plan view of the SiP shown in FIG. 1 according to the present embodiment;

FIG. 3 is a cross sectional view taken along the line III-III′ of the SiP shown in FIG. 1;

FIG. 4 is a plan view of the SiP according to the present embodiment;

FIG. 5 is a cross sectional view taken along the line V-V′ of the SiP shown in FIG. 4;

FIG. 6 is a plan view of the SiP according to the present embodiment;

FIG. 7 is a cross sectional view taken along the line VII-VII′ of the SiP shown in FIG. 1;

FIG. 8 is a plan view of the SiP according to the present embodiment;

FIG. 9 is a cross sectional view taken along the line IX-IX′ of the SiP shown in FIG. 8; and

FIG. 10 is a part of a plan view of the conventional semiconductor system.

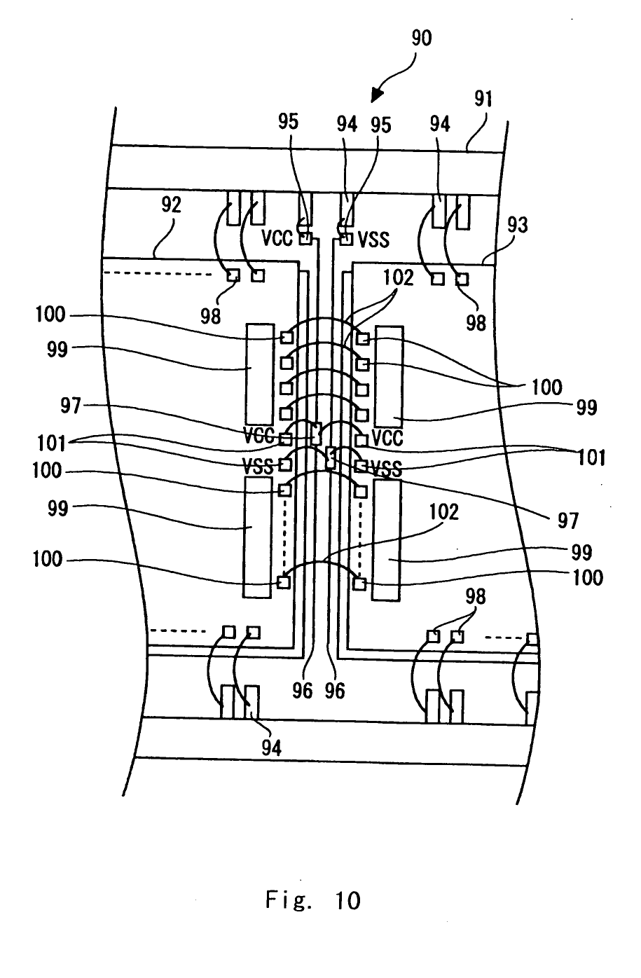

### DETAILED DESCRIPTION OF REFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

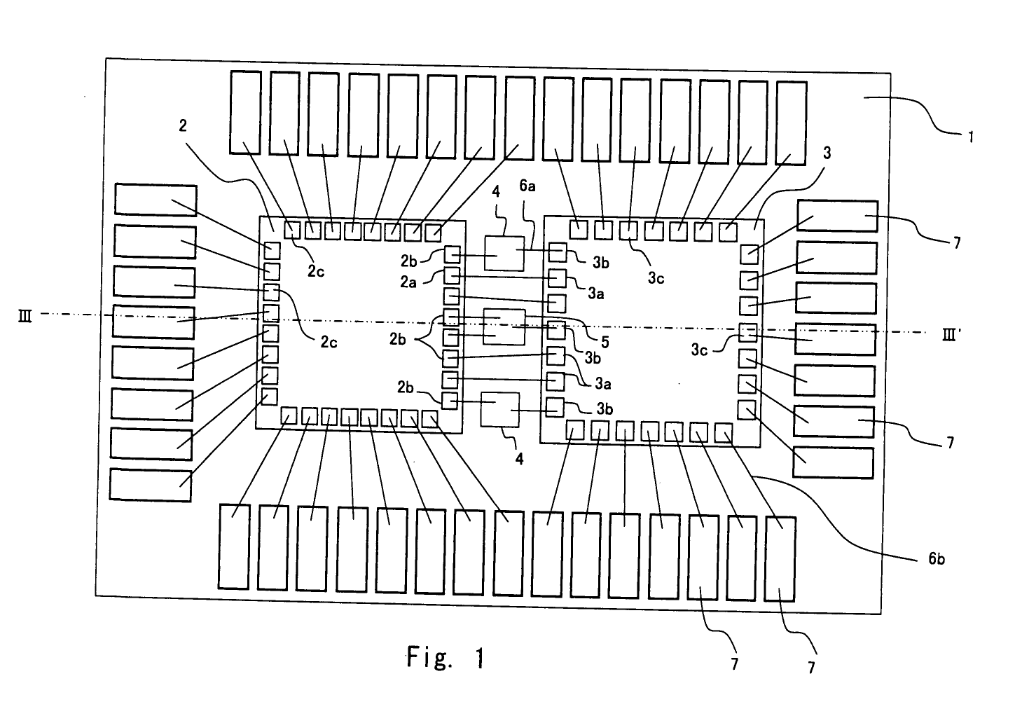

The present embodiment will now be described in detail with reference to the drawings. The present embodiment is the one in which the present invention is applied to an SiP. FIG. 1 shows a plan view of the SiP according to the present embodiment. As shown in FIG. 1, a first semiconductor chip (hereinafter referred to as first chip) 2, a second semiconductor chip (hereinafter referred to as second chip) 3, a plurality of power supply pads 4, a plurality of ground pads 5, and a plurality of peripheral pads 7 are formed on a substrate 1 formed by a plurality of layers in the SiP.

The first chip 2 has a plurality of first connecting pads 2a arranged substantially in line along a side in which the first chip 2 and the second chip 3 face with each other (hereinafter referred to as facing side). The first chip 2 also has a plurality of first connecting pads 2c arranged along sides other than the facing side. The second chip 3 has a plurality of second connecting pads 3a arranged substantially in line along the facing side. The second chip 3 also has a plurality of second connecting pads 3c arranged along sides other than the facing side. As stated below, the power supply pads 4 are connected to a power supply layer formed in the substrate 1 and power supply voltage is supplied through the power supply layer. As stated below, the ground pads 5 are connected to a ground layer (GND layer) formed in the substrate 1 and ground voltage is supplied through the GND layer. The power supply pads 4 and the ground pads 5 are formed between the first chip 2 and the second chip 3 on the substrate 1. The plurality of peripheral pads 7 are the pads for power supply, pads for ground, or pads for signal depending on the function of the first connecting pads 2c or the second connecting pads 3c connected to each peripheral pad 7 and are connected to solder balls formed in a rear surface of the substrate 1 through the wirings of an inner layer of the substrate 1 or a plane. The peripheral pads 7 are connected to the first connecting pads 2c or the second connecting pads 3c through the bonding wires 6b. In other words, the peripheral pads 7 supply power supply voltage or ground voltage to the semiconductor chip in the SiP and transmit/receive signal between the semiconductor chip in the SiP and an external part of the SiP.

A direction in which the first connecting pads 2a and the second connecting pads 3a are arranged substantially inline along the facing side is called pad line direction. In the present embodiment, the first connecting pads 2a not connected to the second connecting pads 3a formed on the second chip 3 are called third pads 2b. The second connecting pads 3a that are not connected to the first connecting pads 2a are called fourth pads 3b. When tilt of the bonding wires 6a is adjusted, the third pads 2b function as tilt adjustment pads. The tilt adjustment pads are the pads adjusting tilt when the bonding wires 6a tilt from a direction orthogonal to the facing side for more than a predetermined degree on the plane. The tilt adjustment pads are unconnected pads that are not connected to the second connecting pads 3a. As stated below, the fourth pads 3b may function as tilt adjustment pads when the tilt of the bonding wires 6a is large and it is needed to adjust the tilt more correctly. In other words, the third pads 2b are redundant pads that are not connected to the second connecting pads 3a. The fourth pads 3b are also the redundant pads that are not connected to the first connecting pads 2a. However, the third pads 2b and the fourth pads 3b can be used for tilt adjustment as stated above. Further, the third pads 2b and the fourth pads 3b are connected to the power supply pads or the ground pads to stabilize potentials of the first chip 2 and the second chip 3.

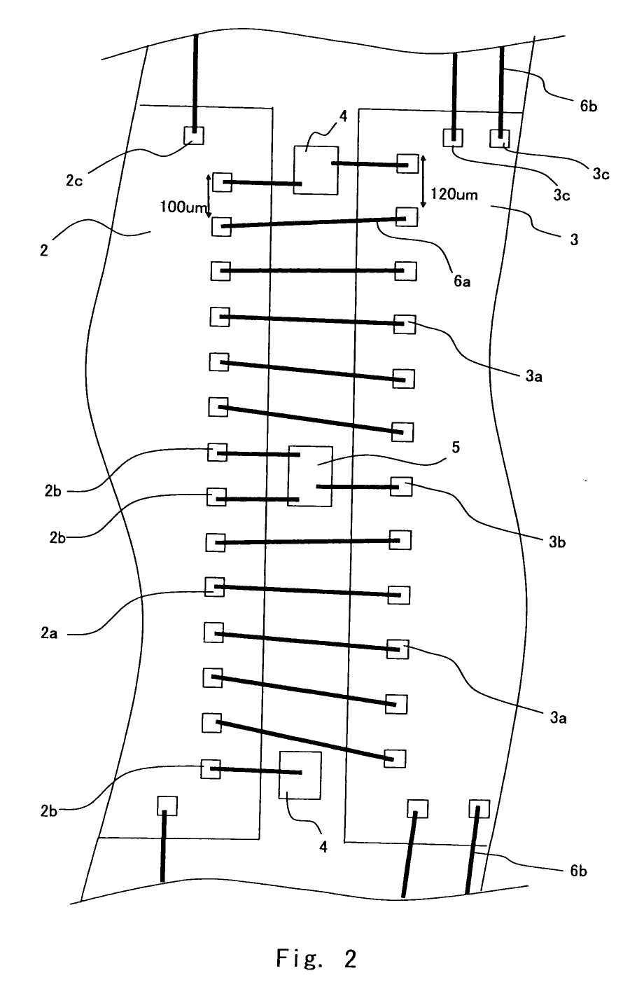

Referring now to FIG. 2, a part of the SiP shown in FIG. 1 is shown. In FIG. 2, the numbers of first connecting pads 2a, third pads 2b, second connecting pads 3a, and fourth pads 3b are changed from those in FIG. 1 for the sake of description. The configurations of the first chip 2 and the second chip 3 of the present embodiment will be described in detail with reference to FIG. 2. As shown in FIG. 2, the first chip 2 and the second chip 3 are formed on the substrate 1. The first chip 2 has a plurality of first connecting pads 2a and the second chip 3 has a plurality of second connecting pads 3a along the facing side of the first chip 2 and the second chip 3. In the present embodiment, the pad pitches of the first connecting pads 2a formed on the first chip 2 and the second connecting pads 3a formed on the second chip 3 are different. Therefore, some of the first connecting pads 2a are called the third pads 2b. The first chip 2 has the first connecting pads 2c in other sides than the facing side and the second chip 3 has the second connecting pads 3c in other sides than the facing side. The first connecting pads 2c and the second connecting pads 3c are connected to the peripheral pads 7 that are not shown through the bonding wires 6b. The pad pitch of the first connecting pads 2a is 100 μm, and the pad pitch of the second connecting pads 3a is 120 μm, for example. The power supply pads 4 connected to the power supply layer and the ground pads 5 connected to the ground layer are provided between the first chip 2 and the second chip 3.

We now assume that the pad pitches of the first connecting pads 2a and the second connecting pads 3a are different. Then the first connecting pads 2a and the second connecting pads 3a formed substantially in line on each chip along the facing side are sequentially connected from the connecting pads of its ends. Because the pad pitches of the first pads 2a and the second pads 3a are different, the bonding wires 6a connecting the first connecting pads 2a and the second connecting pads 3a tilt from the direction orthogonal to the facing side on the plane.

Therefore, in the present embodiment, the third pads 2b function as the tilt adjustment pads for adjusting the tilt of the bonding wires 6a when the bonding wires 6a tilt from the direction orthogonal to the facing side for more than the predetermined degree. When the tilt of the bonding wires 6a is large, a plurality of third pads 2b that are adjacent with each other can function as the tilt adjustment pads. The fourth pads 3b can also function as the tilt adjustment pads for the purpose of adjusting the tilt of the bonding wires 6a more correctly. Then the first connecting pads 2a and the second connecting pads 3a are connected so that the tilt of the bonding wires 6a is less than the predetermined degree. The number of third pads 2b is preferably larger than the number of fourth pads 3a in this embodiment because the pad pitch of the first connecting pads 2a is shorter than the pad pitch of the second connecting pads 3a.

By having such a structure, it is possible to connect the bonding wires 6a connecting the first connecting pads 2a and the second connecting pads 3a to be substantially orthogonal to the facing side on the plane. Therefore, since it is possible to make the wiring length of the bonding wires substantially shortest, noise of the signal which is transmitted and received through the bonding wires 6a can be reduced. Moreover, by providing the bonding wires 6a to be substantially orthogonal to the facing side, it is possible to prevent the wiring length of the bonding wires 6a from being increased on the plane. Therefore, when the bonding wires 6a are encapsulated with a resin, for example, the bonding wires 6a can be prevented from shorting out.

In the present embodiment, the power supply pads 4 and the ground pads 5 are provided between the first chip 2 and the second chip 3 on the substrate 1. Then the third pads 2b and the fourth pads 3b are connected to the power supply pads 4 or the ground pads 5. Therefore, potentials of the first chip 2 and the second chip 3 can be stabilized by providing pads supplying power supply voltage and ground voltage to the first chip 2 and the second chip 3.

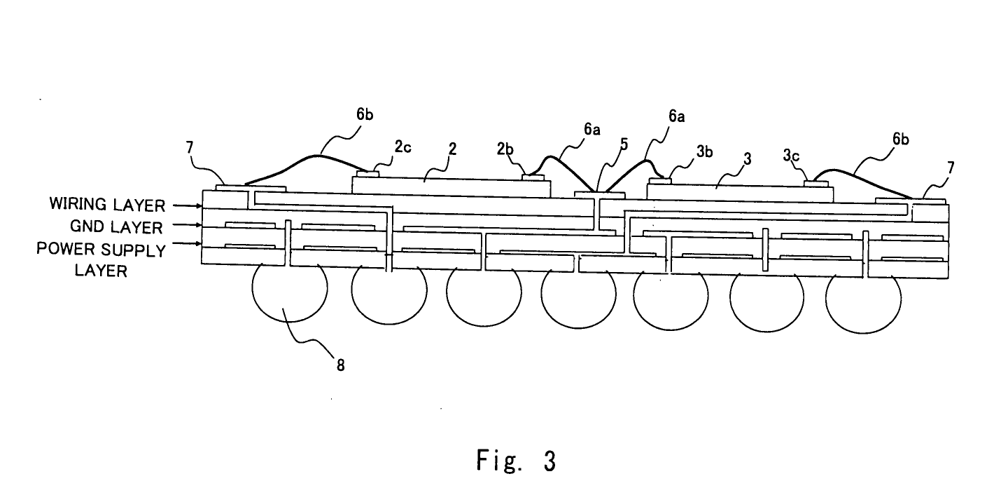

Referring now to FIG. 3, a cross sectional view of the SiP according to the present embodiment is shown. FIG. 3 is the cross sectional view taken along the line III-III′ of the SiP shown in FIG. 1. As shown in FIG. 3, the substrate 1 is formed by stacking a plurality of wiring layers. For example, the power supply layer is formed in a first layer, the ground layer is formed in a second layer, and a wiring layer is formed in a third layer. The plurality of peripheral pads 7 formed on the substrate 1 are connected to the solder balls 8 formed in the rear surface of the substrate 1, for example. The peripheral pads 7 are transmission and reception pads performing transmission and reception of the signal output/input to/from the SiP through the solder balls 8. The peripheral pads 7 are connected to the power supply layer, for example, and the peripheral pads 7 are power supply pads supplying power supply voltage through the power supply layer.

In the present embodiment, the first connecting pads 2a that are not connected to the second connecting pads 3a are called the third pads 2b when the pad pitches of the first connecting pads 2a formed on the first chip 2 and the second connecting pads 3a formed on the second chip 3 are different. The second connecting pads 3a that are not connected to the first connecting pads 2a may be called the fourth pads 3b. When the bonding wires 6a connecting the first connecting pads 2a and the second connecting pads 3a tilt from the direction orthogonal to the facing side for more than the predetermined degree on the plane, the third pads 2b function as tilt adjustment pads. In such a case, the fourth pads 3b can function as tilt adjustment pads. In summary, the third pads 2b or the fourth pads 3b in which the first connecting pads 2a and the second connecting pads 3a are not connected with each other is provided. When the tilt adjustment is performed when the bonding wires 6a tilt for more than the predetermined degree, the third pads 2b function as the tilt adjustment pads. The fourth pads 3b can also function as the tilt adjustment pads. In such a case, the number of third pads 2b is larger than the number of fourth pads 3b because the third pads 2b have shorter pad pitches. Each of the third pads 2b and the fourth pads 3b is connected to the power supply pads 4 or the ground pads 5 formed between the first chip 2 and the second chip 3 on the substrate 1. Therefore, the bonding wires 6a can be formed to be substantially orthogonal to the side in which the first chip 2 and the second chip 3 face with each other on the plane, which makes it possible to make the length of the bonding wire substantially shortest. Therefore, when the bonding wires 6a are encapsulated with a resin, for example, the bonding wires 6a can be prevented from shorting out. Further, by connecting the third pads 2b and the fourth pads 3b to the power supply pads 4 or the ground pads 5, the area of the substrate supplying power supply voltage or ground voltage supplied to the first chip 2 and the second chip 3 can be increased, which makes it possible to stabilize the potentials of the first chip 2 and the second chip 3.

In the present embodiment, the third pads 2b and the fourth pads 3b are connected to the power supply pads 4 or the ground pads 5. However, other pads than the power supply pads 4 and the ground pads 5 may be connected to the third pads 2b and the fourth pads 3b. Nothing may be connected to the third pads 2b and the fourth pads 3b. Not all the third pads 2b or the fourth pads 3b may be connected to the power supply pads 4 or the ground pads 5.

### Second Embodiment

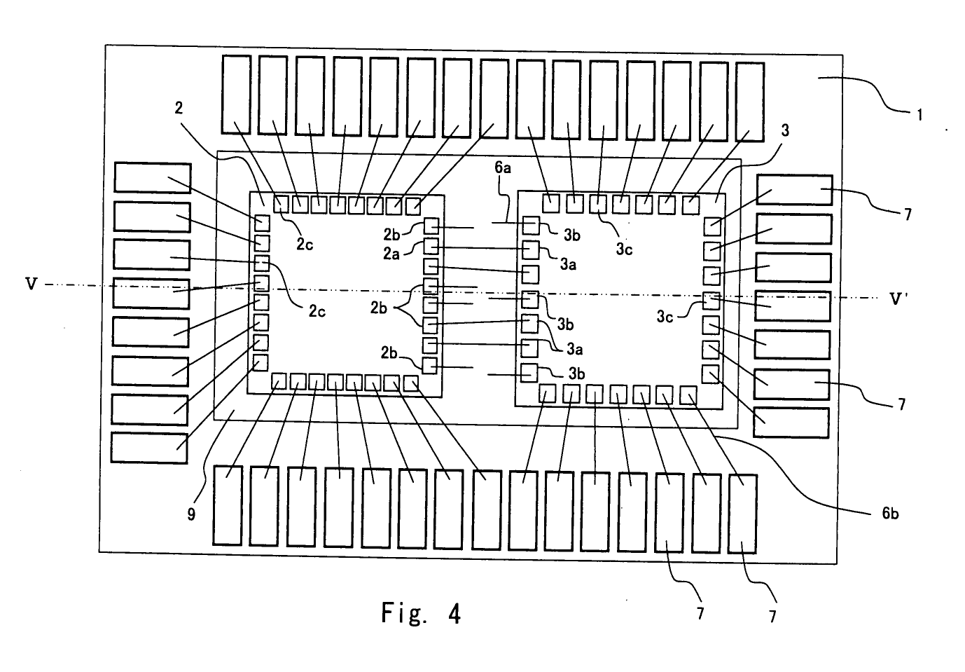

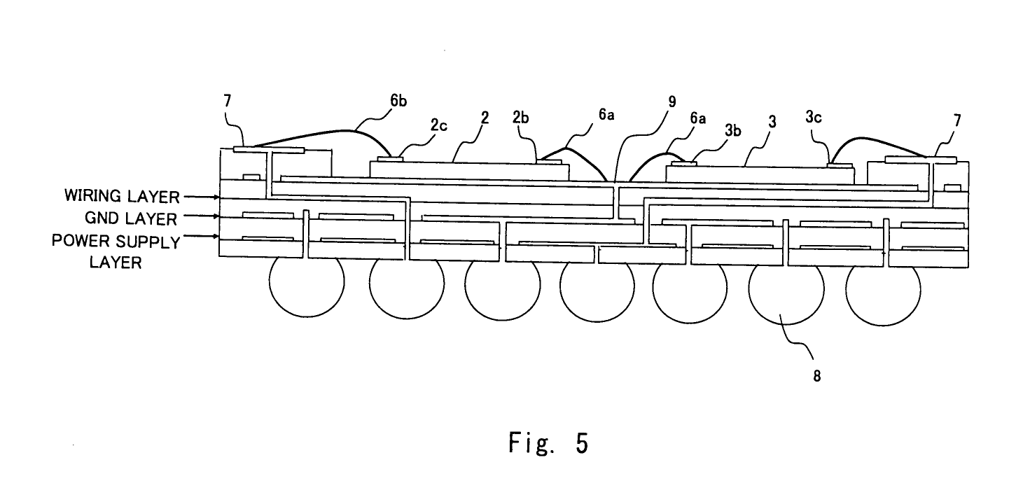

Referring now to FIGS. 4 and 5, the SiP according to the second embodiment will be described. FIG. 4 is a plan view of the SiP according to the second embodiment. In the SiP according to the second embodiment shown in FIGS. 4 and 5 described below, the same reference symbols are given to the same components as in the first embodiment shown in FIGS. 1 to 3 and the the detailed description thereof is omitted.

The SiP shown in FIG. 4 is different from the first embodiment shown in FIGS. 1 to 3 in that the SiP shown in FIG. 4 has a chip mounting substrate 9 connected to the ground on the substrate 1. The chip mounting substrate 9 is connected to the ground layer in the substrate 1 and ground voltage is supplied to the chip mounting substrate 9 through the ground layer as stated below. In other words, the chip mounting substrate 9 and the plurality of peripheral pads 7 are formed on the substrate 1 and the first chip 2 and the second chip 3 are formed on the chip mounting substrate 9. Then each of the third pads 2b formed on the first chip 2 and the fourth pads 3b formed on the second chip 3 is connected to the chip mounting substrate 9. The chip mounting substrate 9 is connected to the ground layer in the substrate 1 and ground voltage is supplied to the chip mounting substrate 9 through the ground layer. The first chip 2 and the second chip 3 are formed on the ground layer 9.

FIG. 5 shows a cross sectional view taken along the line V-V′ of the SiP shown in FIG. 4. As shown in FIG. 5, the chip mounting substrate 9 and the plurality of peripheral pads 7 are formed on the substrate 1 formed by stacking the plurality of wiring layers. The first chip 2 and the second chip 3 are formed on the chip mounting substrate 9. The third pads 2b formed on the first chip 2 are connected to the chip mounting substrate 9 through the bonding wires 6a. The fourth pads 3b are connected to the chip mounting substrate 9 through the bonding wires 6a. Each of the first connecting pads 2c and the second connecting pads 3c are connected to the peripheral pads 7 through the bonding wires 6b.

In the present embodiment which is thus formed, the first chip 2, the second chip 3, the third pads 2b, and the fourth pads 3b are connected to the chip mounting substrate 9 to which ground voltage is supplied. In other words, a substrate supplying ground voltage supplied to the first chip 2 and the second chip 3 is provided. Therefore, potential supplied to the first chip 2 and the second chip 3 can be more stabilized.

### Third Embodiment

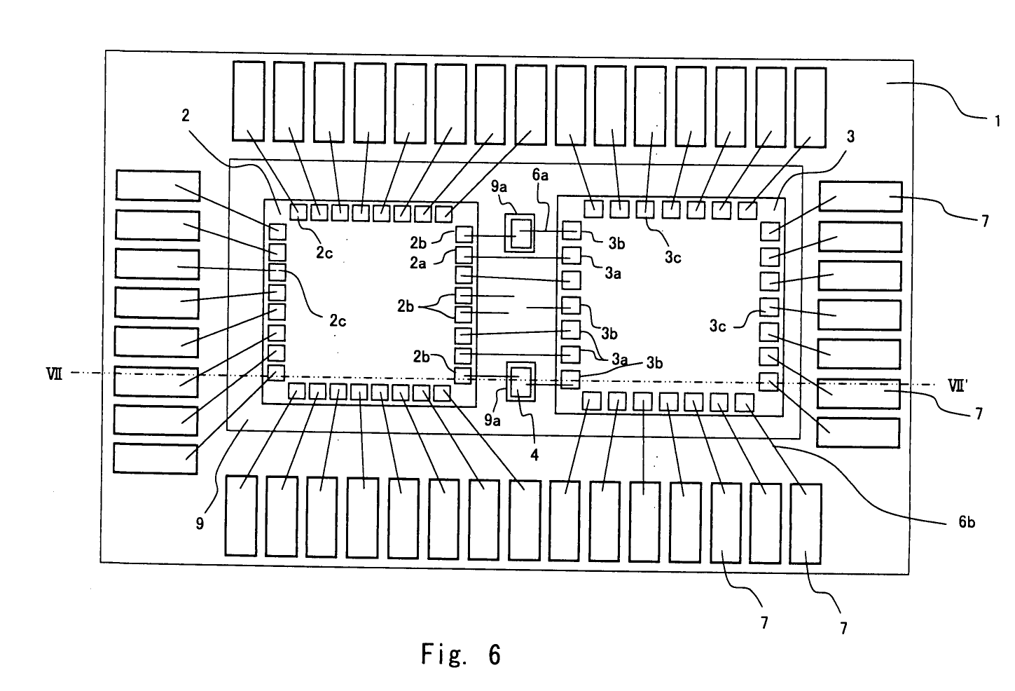

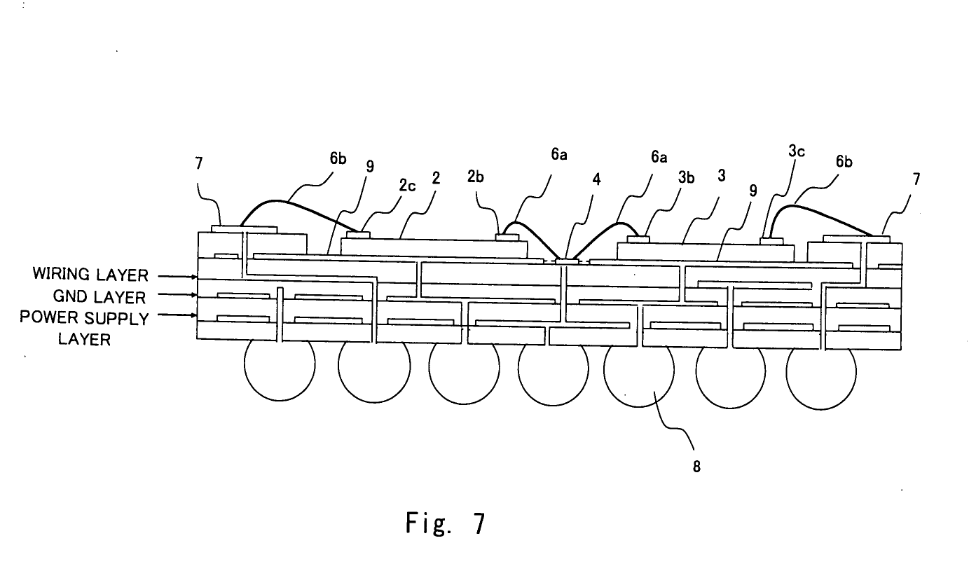

Referring now to FIGS. 6 and 7, the SiP according to the third embodiment will be described. FIG. 6 is a plan view of the SiP according to the third embodiment. In the SiP according to the third embodiment shown in FIGS. 6 and 7 described below, the same reference symbols are given to the same components as in the first embodiment shown in FIGS. 1 to 3 and the the detailed description thereof is omitted.

The SiP shown in FIG. 6 is different from the first embodiment shown in FIGS. 1 to 3 in that the SiP shown in FIG. 6 has the chip mounting substrate 9 connected to the ground on the substrate 1 and apertures 9a for exposing the power supply pads 4 on the chip mounting substrate 9. Therefore, the power supply pads 4 connected to the power supply are formed on the substrate 1 and the plurality of peripheral pads 7 such as signal pads are formed along the periphery of the substrate 1. The power supply pads 4 are formed between the first chip 2 and the second chip 3 formed on the chip mounting substrate 9. The chip mounting substrate 9 is formed on the substrate 1 so that the chip mounting substrate 9 covers other part than the power supply pads 4 and the peripheral pads 7. Therefore, the power supply pads 4 are put into the apertures 9a. The first chip 2 and the second chip 3 are formed on the chip mounting substrate 9. Then the first connecting pads 2a or the like are formed on each of the first chip 2 and the second chip 3. Then the first connecting pads 2a formed on the first chip 2 and the second connecting pads 3a formed on the second chip 3 are connected to each other. The third pads 2b formed on the first chip 2 and the fourth pads 3b formed on the second chip 3 are connected to the power supply pads 4 or the chip mounting substrate 9.

In the present embodiment, the power supply pads 4 are formed on the substrate 1. The power supply pads 4 are formed in the apertures 9a of the chip mounting substrate 9 and the first chip 2 and the second chip 3 are formed on the chip mounting substrate 9. Then the third pads 2b and the fourth pads 3b are connected to the chip mounting substrate 9 formed on the substrate 1 or to the power supply pads 4 formed between the first chip 2 and the second chip 3. Therefore, potentials of the first chip 2 and the second chip 3 are stabilized by providing the substrate supplying power supply voltage and the substrate supplying ground voltage to the first chip 2 and the second chip 3. In the present embodiment, the chip mounting substrate 9 has apertures 9a in which the power supply pads 4 are formed and the first chip 2 and the second chip 3 are provided on the chip mounting substrate 9. However, two chip mounting substrates may be provided on the substrate 1 and the first chip 2 or the second chip 3 may be formed on each chip mounting substrate, for example.

FIG. 7 is a cross sectional view taken along the line VII-VII′ of the SiP according to the third embodiment that is thus formed. As shown in FIG. 7, the first redundant pads 2b formed on the first chip 2 are connected to the power supply pads 4 formed on the substrate 1 through the bonding wires 6a or connected to the chip mounting substrate 9 (not shown). The second redundant pads 3b formed on the second chip 3 are connected to the power supply pads 4 formed on the substrate 1 through the bonding wires 6a or connected to the chip mounting substrate 9 (not shown). Each of the first connecting pads 2c and the second connecting pads 3c are connected to the peripheral pads 7 through the bonding wires 6b. Therefore, potentials of the first chip 2 and the second chip 3 are stabilized.

### Fourth Embodiment

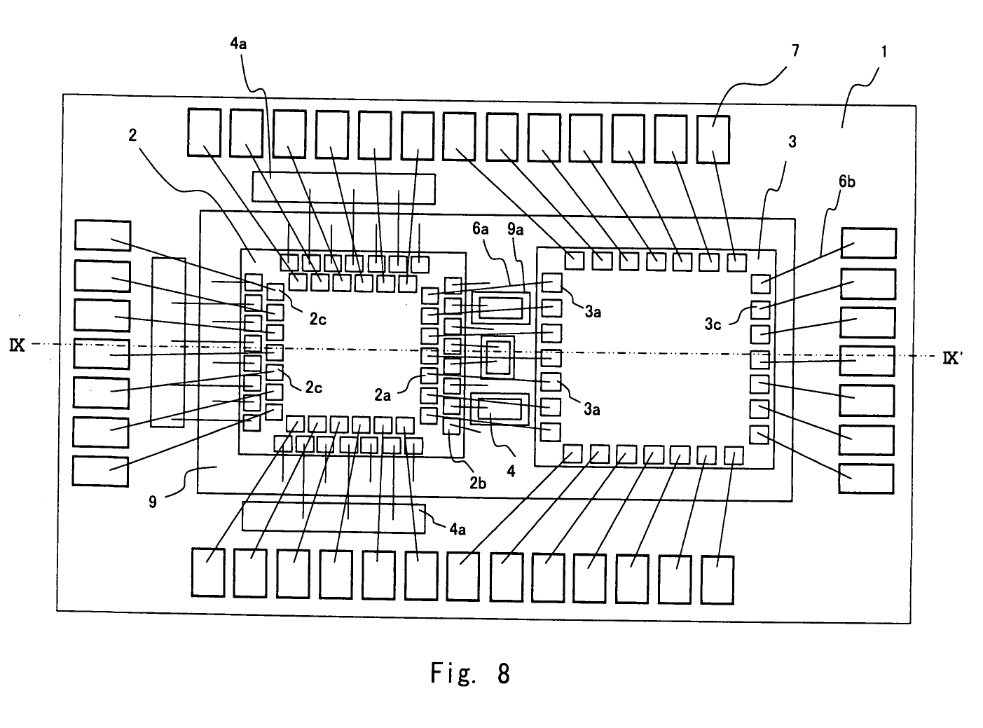

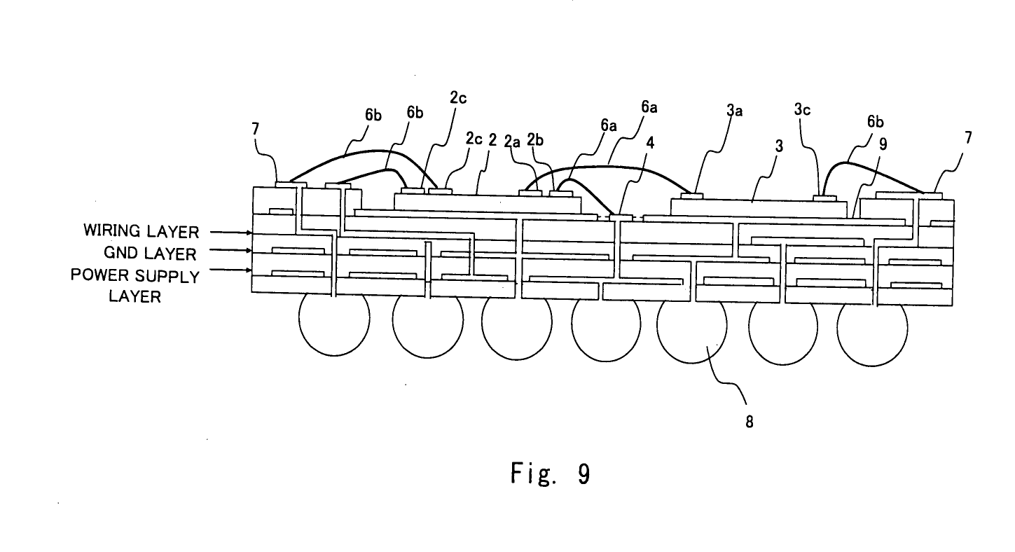

Referring now to FIGS. 8 and 9, the SiP according to the fourth embodiment will be described. FIG. 8 is a plan view of the SiP according to the fourth embodiment. In the SiP according to the fourth embodiment shown in FIGS. 8 and 9 described below, the same reference symbols are given to the same components as in the first embodiment shown in FIGS. 1 to 3 and the the detailed description thereof is omitted.

The SiP shown in FIG. 8 is different from the first embodiment shown in FIGS. 1 to 3 in that the SiP shown in FIG. 8 has the chip mounting substrate 9 on the substrate 1 and the first connecting pads 2a and 2c each of which arranged in two lines. The chip mounting substrate 9 is connected to the ground and has apertures 9a. The power supply 4 is formed in the apertures 9a. The first connecting pads 2a arranged in the side facing the second chip 3 along the edge facing the second chip 3 are called the third pads 2b. This is because if the first connecting pads 2a that are facing the second chip 3 but are not arranged in the edge facing the second chip 3 are connected to the chip mounting substrate 9 or the power supply pads 4, the bonding wires 6a can be broken because the bonding wires 6a may touch the first chip 2. Therefore, in the present embodiment, the first connecting pads 2a that are in the side facing the second chip 3 are called the third pads 2b and the first connecting pads 2b are connected to the power supply pads 4 or the chip mounting substrate 9.

Preferably, the first connecting pads 2a and the third pads 2b arranged in two lines are alternately arranged to facilitate connecting of the bonding wires 6a. For example, the first connecting pads 2a and the third pads 2b are preferably formed in a zigzag pattern as shown in FIG. 8. The power supply pads 4a connected to the power supply may be provided on the substrate 1 so as to surround the first chip 2. The first connecting pads 2c arranged in other sides than the facing side and along the edges of the first chip 2 are connected to the chip mounting substrate 9 or the power supply pads 4a. Therefore, the bonding wires 6b can be prevented from being broken. Potential of the first chip 2 can be stabilized by further providing the power supply pads 4a which are the substrates supplying power supply voltage to the first chip 2.

FIG. 9 is a cross sectional view taken along the line IX-IX′ of the SiP of the fourth embodiment that is thus formed. As shown in FIG. 9, the third pads 2b formed on the first chip 2 are connected to the power supply pads 4 formed on the substrate 1 through the bonding wires 6a or connected to the chip mounting substrate 9 (not shown). The first connecting pads 2a are connected to the second connecting pads 3a. Each of the first connecting pads 2c and the second connecting pads 3c is connected to the peripheral pads 7 or the power supply pads 4 through the bonding wires 6b.

In the present embodiment, the first connecting pads 2a and 2c are arranged in two lines. Preferably, the first connecting pads 2a and 2c are arranged in a zigzag pattern, for example. The first connecting pads 2a arranged in the side facing the second chip 3 along the edge facing the second chip 3 are formed as the third pads 2b. The first connecting pads 2a are connected to the second connecting pads 3a and the third pads 2b are connected to the power supply 4 or the chip mounting substrate 9. Therefore, it is possible to prevent the bonding wires 6a connecting pads from being broken. The power supply pads 4a may be provided on the substrate 1 so as to surround the first chip 2. In such a case, the first connecting pads 2c arranged along the edges of the first chip 2 are preferably connected to the power supply pads 4a or the chip mounting substrate 9. In other words, potentials of the first chip 2 and the second chip 3 become more stabilized by forming the power supply pads 4a supplying power supply voltage to the first chip 2 and forming the chip mounting substrate 9 supplying ground voltage to the first chip 2 and the second chip 3.

It is apparent that the present invention is not limited to the above embodiment, but may be modified and changed without departing from the scope and spirit of the invention.

What is claimed is:

1. A semiconductor device comprising:
a first semiconductor chip having first pads arranged at first interval; and
a second semiconductor chip having second pads arranged at second interval, the second interval being larger than the first interval, wherein:
the first semiconductor chip includes the first pads not connected to the second pads; and
the first pads not connected to the second pads function as tilt adjustment pads adjusting tilt of wirings connecting the first pads and the second pads.

2. The semiconductor device according to claim 1,
wherein the first pads not connected to the second pads function as the tilt adjustment pads when the second pads tilt from a direction orthogonal to a side in which the first semiconductor chip and the second semiconductor chip face for more than a predetermined degree.

3. The semiconductor device according to claim 1, comprising;
a first power supply pad connected to a first power supply or a second power supply pad connected to a second power supply, the first power supply pad and the second power supply pad being arranged between the first semiconductor chip and the second semiconductor chip,
wherein the first pads not connected to the second pads are connected to the first power supply pads or the second power supply pads.

4. The semiconductor device according to claim 1, comprising:
the first semiconductor chip and the second semiconductor chip formed on a chip mounting substrate connected to a first power supply,
wherein the first pads not connected to the second pads are connected to the chip mounting substrate.

5. The semiconductor device according to claim 4, wherein;
the chip mounting substrate includes a plurality of apertures; and
the second power supply pads connected to a second power supply are formed in the apertures and the first pads not connected to the second pads are connected to the chip mounting substrate or the second power supply pads.

6. The semiconductor device according to claim 1,
wherein the first pads are arranged in a plurality of lines in a zigzag pattern along sides of the first semiconductor chip.

7. The semiconductor device according to claim 6,
wherein the first pads arranged in the side facing the second semiconductor chip and along an edge facing the second semiconductor chip have pads not connected to the second pads.

8. The semiconductor device according to claim 1,
wherein the second semiconductor chip has the second pads not connected to the first pads.

9. The semiconductor device according to claim 8,
wherein a number of the first pads not connected to the second pads is larger than the number of the second pads not connected to the first pads, both of the first pads not connected to the second pads and the second pads not connected to the first pads being connected to the first power supply pads or the second power supply pads.
